(19) United States
(12) Patent Application Publication
(10) Pub. No.: US 2019/0318050 A1
(43) Pub. Date: Oct. 17, 2019

(54) ENVIRONMENTAL MODIFICATION IN AUTONOMOUS SIMULATION

(71) Applicant: Toyota Research Institute, Inc., Los Altos, CA (US)

(72) Inventors: Samuel Zapolsky, San Francisco, CA (US); Evan Drumwright, Mountain View, CA (US)

(21) Appl. No.: 15/950,263

(22) Filed: Apr. 11, 2018

(51) Int. Cl. G06F 17/50

(52) U.S. Cl. CPC G06F 17/5009; G05D 1/0088

(57) ABSTRACT

Systems and methods for validation of autonomous device control are disclosed herein. The systems and methods can experimentally validate control models, using randomness to account for error in environmental parameters as received by the simulation. The system and method can include generating modified environmental parameters using initial environmental parameters. A simulation can then be generated using the one or more modified environmental parameters and presented to a plurality of control models for an autonomous device. A performance metric for each of at least two of the plurality of control models can then be determined using a corresponding information set. Finally, one of the plurality of control models can be selected based on the performance metric.

### TECHNICAL FIELD

Embodiments described herein generally relate to systems and methods for modifying a simulated environment. More specifically, the embodiments generally relate to systems and methods for using randomness in modifying an environment for validation of control models.

### BACKGROUND

A robotic system may exhibit unknown or unexpected behaviors due to uncertain or errors. Roboticists desire to understand faults of a robotic system before the faults are observed in a physical robot system. As such, simulations are generally designed and run in testing performance of autonomous devices. Simulations generally include a simulated environment. The simulated environment is a sampling of an actual environment, which is generalized into various shapes and structures. Using the simulated environment, the autonomous device is then allowed to simulate performance, according to the autonomous device's control systems, of various movements and actions. The generalized shapes and structures, estimated from data retrieved from a set of sensors, are the objects in the simulation with which the autonomous device will interact. This allows an operator to estimate how the autonomous device will perform in real world operation.

### SUMMARY

Systems and methods for creating and using probability distributions in environmental parameters for autonomous simulation are disclosed herein. In one embodiment, a probabilistic simulation system for validation of autonomous device control is disclosed. The system can include one or more processors and a memory communicably coupled to the one or more processors. The memory can include a generation module including instructions that when executed by the one or more processors cause the one or more processors to generate one or more modified environmental parameters using one or more initial environmental parameters, and to generate a simulation using the one or more modified environmental parameters. The memory can further include a presentation module including instructions that when executed by the one or more processors cause the one or more processors to present the simulation to a plurality of control models for an autonomous device, wherein each of the plurality of control models provides an information set. The memory can further include a selection module including instructions that when executed by the one or more processors cause the one or more processors to determine a performance metric for each of at least two of the plurality of control models using the corresponding information set, and to select one of the plurality of control models based on the performance metric.

In another embodiment, a non-transitory computer-readable medium for validation of autonomous device control is disclosed. The non-transitory computer-readable medium can store instructions that when executed by one or more processors cause the one or more processors to generate one or more modified environmental parameters using one or more initial environmental parameters. The non-transitory computer-readable medium can further store instructions that generate a simulation using the one or more modified environmental parameters. The non-transitory computer-readable medium can further store instructions that present the simulation to a plurality of control models for an autonomous device, wherein each of the plurality of control models provides an information set. The non-transitory computer-readable medium can further store instructions that determine a performance metric for each of at least two of the plurality of control models using the corresponding information set. The non-transitory computer-readable medium can further store instructions that select one of the plurality of control models based on the performance metric.

In another embodiment, a method for validation of autonomous device control is disclosed. The method can include generating one or more modified environmental parameters using one or more initial environmental parameters. The method can further include generating a simulation using the one or more modified environmental parameters. The method can further include presenting the simulation to a plurality of control models for an autonomous device, wherein each of the plurality of control models provides an information set. The method can further include determining a performance metric for each of at least two of the plurality of control models using the corresponding information set. The method can further include selecting one of the plurality of control models based on the performance metric.

### BRIEF DESCRIPTION OF THE DRAWINGS

So that the manner in which the above recited features of the present disclosure can be understood in detail, a more particular description of the disclosure, briefly summarized above, may be had by reference to the embodiments, some of which are illustrated in the appended drawings. It is to be noted, however, that the appended drawings illustrate only typical embodiments of this disclosure and are therefore not to be considered limiting of its scope. The disclosure may admit to other equally effective embodiments.

FIG. 1 is a block diagram of a vehicle useable as part of a probabilistic simulation, according to embodiments described herein.

FIG. 2 is a block diagram of a computing device incorporating a probabilistic simulation system, according to embodiments described herein

FIG. 3 is an illustration of the probabilistic simulation system for validation of autonomous device control, according to embodiments described herein.

FIG. 4 is a schematic of the probabilistic simulation system, according to one or more embodiments.

FIGS. 5A and 5B depict simulations incorporating the probabilistic simulation system, according to embodiments described herein.

FIG. 6 is a flow diagram of a method for validation of autonomous device control, according to one or more embodiments.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments disclosed herein describe probabilistic simulation systems and methods for validation of autonomous device control. A robotic system may exhibit unknown or unexpected behaviors due to uncertainty or errors. Roboticists desire to understand faults of a robotic system before the faults are observed in a physical robot system. Simulations are performed to gain a better understanding of unexpected and/or undesirable behavior so that such behaviors are prevented in the physical robot system. In some examples, random error (referred to herein as “noise”) can be introduced into a simulation model by perturbing inputs into the robot, such as sensor data, state vectors, and the like. However, structured noise leads to a structured output. Thus, there is an expected uncertainty in the output.

Embodiments of the present disclosure introduce error into physical parameters of the simulation, including those of the autonomous device, as well as other objects in the environment. These parameters can include friction, inertia, lengths of links, geometries, weight, surface roughness, and the other measures. For example, there are manufacturing tolerances that account for some uncertainty of the robot as well as objects that the robot encounters. Although these physical parameters are static in the physical world, embodiments of the present disclosure introduce errors (either structured or unstructured) of these physical parameters that are then provided to a plurality of simulation models that are simultaneously executed. Embodiments of the present application can be more clearly understood with relation to the figures and the description below.

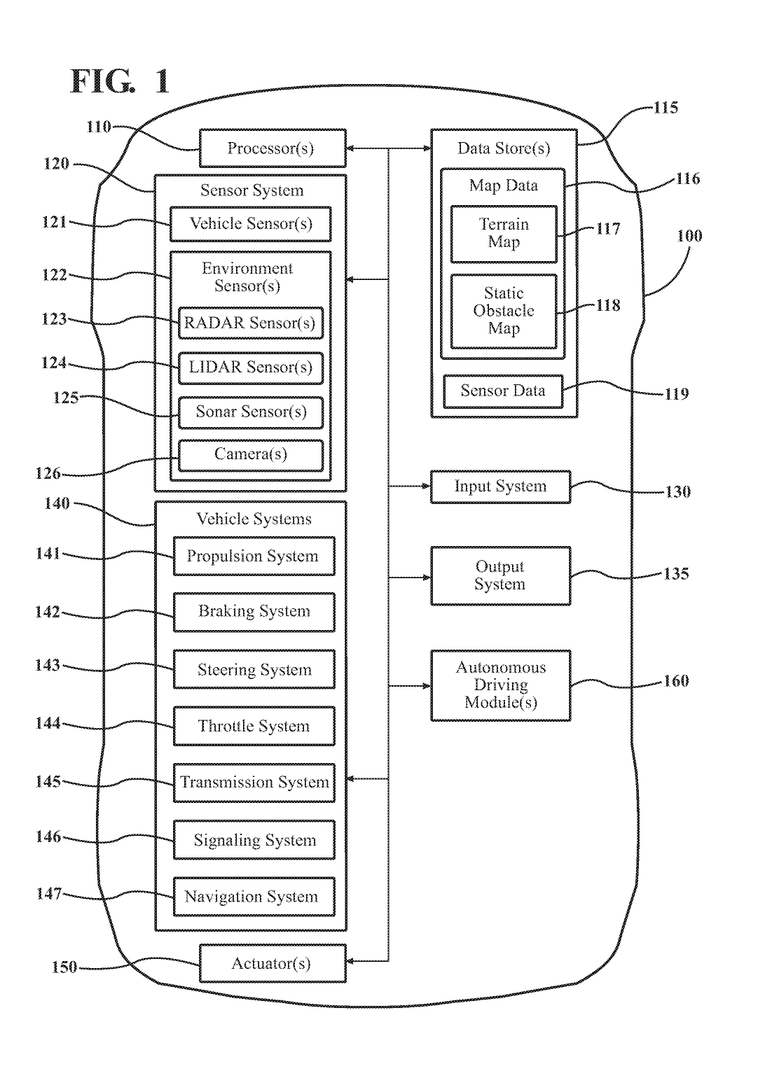

Referring to FIG. 1, an example of an autonomous device, specifically a vehicle 100, is illustrated. The vehicle 100 can receive a selected control model, as selected using the systems and methods below. Further, the vehicle 100 can be modeled as described here, in the simulations described below. As used herein, a “vehicle” is any form of motorized transport. In one or more implementations, the vehicle 100 can be an automobile. In some implementations, the vehicle 100 may be any other form of motorized transport that, for example, can operate autonomously, semi-autonomously, or manually by an in-vehicle operator. The vehicle 100 can include a probabilistic simulation system or capabilities to support or interact with a probabilistic simulation system, and thus benefits from the functionality discussed herein. While arrangements will be described herein with respect to automobiles, it will be understood that embodiments are not limited to automobiles. The autonomous device can be any form of machination capable of independently or semi-independently interacting with a simulated environment, including a robot, a mechanical arm, a vehicle, and others. Instances of vehicle, as used throughout, are equally applicable to any autonomous device.

The vehicle 100 also includes various elements. It will be understood that in various embodiments it may not be necessary for the vehicle 100 to have all of the elements shown in FIG. 1. The vehicle 100 can have any combination of the various elements shown in FIG. 1. Further, the vehicle 100 can have additional elements to those shown in FIG. 1. In some arrangements, the vehicle 100 may be implemented without one or more of the elements shown in FIG. 1. While the various elements are shown as being located within the vehicle 100 in FIG. 1, it will be understood that one or more of these elements can be located external to the vehicle 100. Further, the elements shown may be physically separated by large distances.

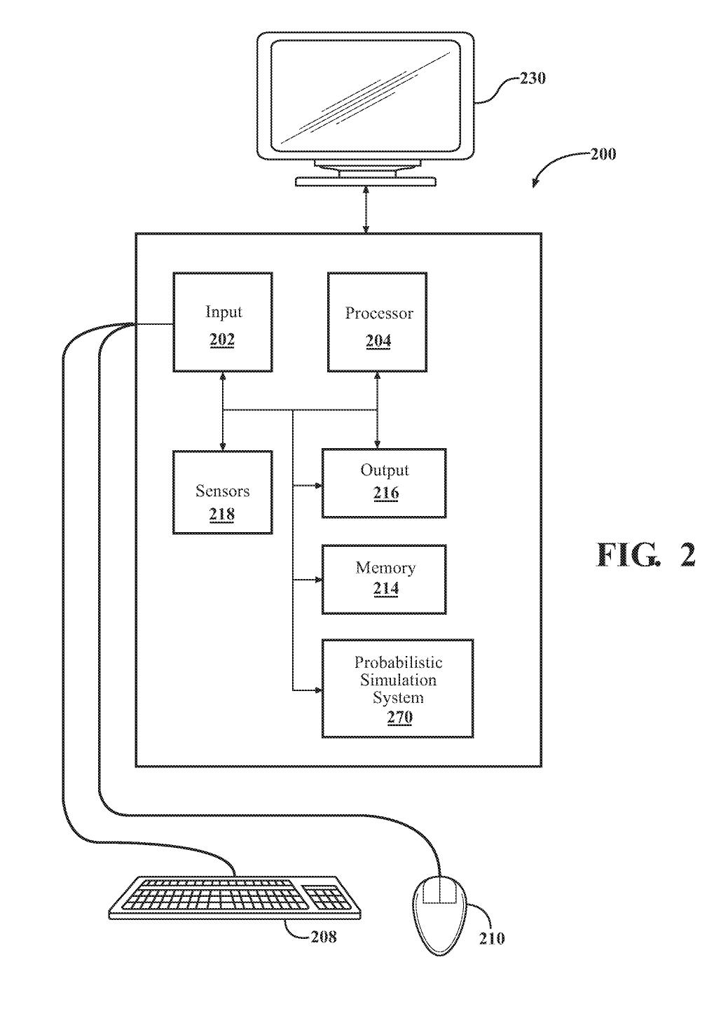

Some of the possible elements of the vehicle 100 are shown in FIG. 1 and will be described along with subsequent figures. However, a description of many of the elements in FIG. 1 will be provided after the discussion of FIGS. 2-6 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements.

In embodiments described herein, the vehicle 100 can be in communication with a computing device 200. The vehicle 100 or other autonomous device being in communication with the computing device 200 refers to any forms of direct or indirect communication between the computing device 200 and the vehicle 100, including direct wired communication, communication through one or more intermediary computing devices, communication through the cloud, or combinations thereof. The communication can be performed through the use of a variety of wired or wireless networks. In some embodiments, the computing device 200 is a server which is remote from the vehicle 100. In further embodiments, the computing device 200 can be integrated into the vehicle 100, such as an embedded system. The computing device 200 can include a probabilistic simulation system 270 that is implemented to perform methods and other functions as disclosed herein.

Referring to FIG. 2, an example of a computing device 200 having the probabilistic simulation system 270 is illustrated. The computing device 200 can be any appropriate type of computing device such as, but not limited to, a server, a personal computer (PC), workstation, embedded computer, or stand-alone device with a computational unit, such as a microprocessor, DSP (digital signal processor), FPGA (field programmable gate array), or ASIC (application specific integrated circuit). Shown here, the computing device 200 is a server connected with a display device 230. While arrangements will be described herein with respect to servers, it will be understood that embodiments are not limited to servers. In some implementations, the computing device 200 can be any other form of computing device that, for example, can receive data transmissions from one or more vehicles, send data transmissions to one or more vehicles, and can benefit from the functionality of the probabilistic simulation system discussed herein.

The computing device 200 can have an input 202 for obtaining environmental information of for communication with other computing devices. The input 202 is one or more connections, either wired or wireless, for an input device to the computing device 200. The input 202 can be any suitable communication interface depending on device type and include, but is not limited to, USB (universal serial bus), frame grabber, Ethernet, or Firewire. The computing device 200 further comprises a processor 204, such as a general purpose processor, for use in the data processing and analysis described herein. The processor 204, which can also referred to as a central processing unit (CPU), can be a device which is capable of receiving and executing one or more instructions to perform a task as part of a computing device. In one embodiment, the processor 204 can include a microprocessor such as an application-specific instruction set processor (ASIP), graphics processing unit (GPU), a physics processing unit (PPU), a digital signal processor (DSP), an image processor, a co-processor, or others. Though referenced as the processor 204, it is understood that one or more processors 204 can be used in one or more embodiments described herein, including combinations of processors 204. In some embodiments, the input 202 be connected with sensors 218 (e.g., the sensor system 120 of the vehicle 100, sensors available via infrastructure, etc.), microphones or other active or passive input devices or systems. Shown here, the input 202 is connected with a keyboard 208 and a mouse 210. In further embodiments, the computing device 200 can include a connection 212. The connection 212, which can be wired or wireless, can allow the computing device 200 to communicate with other computing devices, locally or remotely, such as over a network protocol (e.g., Ethernet or similar protocols). The connection 212 can further be connected with remote devices associated with other computing devices, such as the sensors system 120 and the data store 115 as described with reference to the vehicle 100.

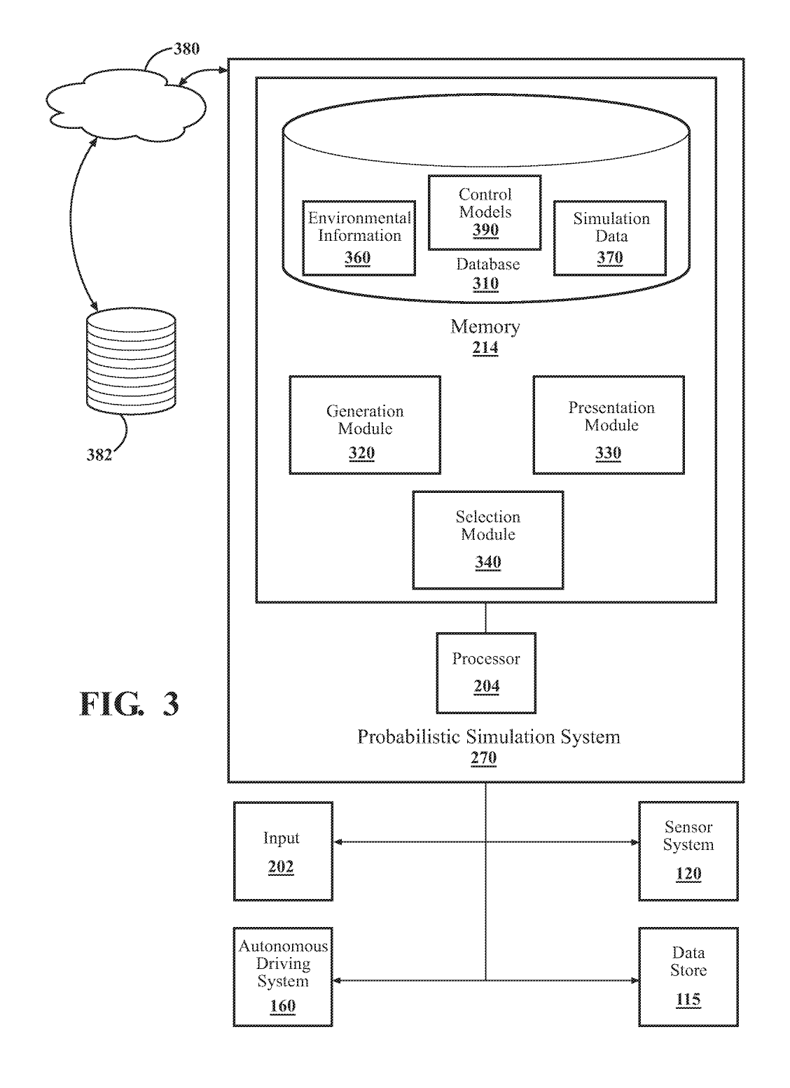

The computing device 200 can further comprise some volatile or non-volatile memory, such as memory 214. The memory 214 can include volatile and/or non-volatile memory. Examples of suitable memory 214 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The memory 214 can be a component of the processor(s) 204, or the memory 214 can be operably connected to the processor(s) 204 for use thereby. The memory 214 can include one or more modules that include computer readable instructions that, when executed by the processor 204, cause the processor 204 to perform methods and functions that are discussed herein. The memory 214 can include a database 310, described with reference to FIG. 3. The memory 214 can contain information related to a reference material for comparison and/or analysis purposes. The computing device 200 can also include output connection 216 for conveying output in a fashion which is usable by the vehicle 100 or a user. In one example, the output connection 216 conveys output to a screen for convenient viewing (e.g., display device 230) or to a control device.

The computing device 200 further includes the probabilistic simulation system 270 that is implemented to perform methods and other functions as disclosed herein relating to selection of control models based on randomized environmental perturbations. The probabilistic simulation system 270 includes a plurality of modules to perform the functions described herein, including a generation module 320, a presentation module 330 and a selection module 340. In one or more embodiments, the probabilistic simulation system 270 can communicate via a wired or wireless connection, depicted as the network 380, with local or remote devices, such as to receive information regarding the simulation of an environment. In one or more embodiments, the probabilistic simulation system 270 can communicate with the vehicle 100, with a server 382, with another computing device 200, or combinations thereof. Further, the probabilistic simulation system 270 can simulate or effect communication within the computing device 200, such as between a simulation and one or more control models 390 to correlate functionality as discussed herein. The probabilistic simulation system 270 can be in communication with the one or more control models 390 to validate the control models in simulation and with the vehicle 100 to provide a validated control model, as described herein.

The probabilistic simulation system 270 is more clearly described with reference to FIG. 3. The probabilistic simulation system 270 can include one or more modules to create a variety of simulations, present said simulations to one or more control models, and select an adopted control model form the one or more control models. The probabilistic simulation system 270 is shown as including a processor 204 from the computing device 200, depicted in FIG. 2. Accordingly, the processor 204 can be a part of the probabilistic simulation system 270, the probabilistic simulation system 270 can include a separate processor from the processor 204 of the computing device 200, the processor 110 of the vehicle 100, or the probabilistic simulation system 270 can access the processor 204 or the processor 110 through a data bus or another communication path. In one embodiment, the probabilistic simulation system 270 includes the memory 214 that stores the generation module 320, the presentation module 330 and the selection module 340. The memory 214 is a random-access memory (RAM), read-only memory (ROM), a hard-disk drive, a flash memory, or other suitable memory for storing the modules 320, 330, and 340. The modules 320, 330, and 340 are, for example, computer-readable instructions that when executed by the processor 204, cause the processor 204 to perform the various functions disclosed herein.

The generation module 320 can generally include instructions that function to control the processor 204 to generate one or more modified environmental parameters using one or more initial environmental parameters. The initial environmental parameters can be derived from an initial environment. As such, the environmental parameters, as used herein, can include all objects within the environment, including the autonomous device. The environment, as used herein, is the virtual environment which is presented to the one or more control models 390 of an autonomous device as part of a simulation, including the parameters of the autonomous device within the environment. The one or more control models can be stored in the database 310. The environment, such as an initial environment, can be a rendition of a real world environment. The generation module 320 can use one or more sensors to collect initial environmental parameters from the real world environment, such as from a sensor system 120, described with reference to FIG. 1. In one or more embodiments, the environment can include one or more environmental parameters. The one or more environmental parameters, including the initial environmental parameters and the modified environmental parameters, can be stored as part of environmental information 360 in the database 310. The environmental parameters provide information regarding the shape, size, boundaries, and other features of the various objects and elements in an environment, such as the initial environment. The environmental parameters can be based on information collected from an actual environment, estimated about an actual environment or hypothesized about an actual or fictitious environment.

In one embodiment, the generation module 320 can modify or alter one or more initial environmental parameters. The modified environmental parameters can then be incorporated into a modified environment. In one or more embodiments, the probabilistic simulation system 270 modifies the one or more initial environmental parameters of the initial environment to introduce uncertainty into environmental elements of the simulation. Environmental parameters can include physical parameters of objects in the environment and physical parameters of the autonomous device. Embodiments herein can employ a Monte Carlo scheme to introduce uncertainty. The Monte Carlo scheme as used herein describes broad class of computational algorithms that rely on repeated random sampling to obtain numerical results. The Monte Carlo scheme applies randomness to solve problems that can be deterministic in principle. The Monte Carlo scheme can be used to introduce random uncertainty into the one or more environmental parameters to create modified environmental parameters. The measured or given values for the environmental parameters can be incorrect or otherwise imprecise. The Monte Carlo scheme can be used to apply randomness to the measured or given values for environmental parameters to overcome this possibility. Over multiple iterations, a significant majority of possible iterations are explored, thus reducing the likelihood that imprecision in environmental measurement results in a real world control model failure.

The environmental parameters can be randomly selected and randomly modified, such as a random modification within a specified range. In one example, the shape of an object in the environment, such as a portion of road or the vehicle 100, could be altered at one or more points within a range of possible or likely widths and depths. The presentation module 330 can modify the one or more environmental parameters according to a variety of approaches, including random modification, bounded random modification (modification with a specified range), selected random modification (modification in response to previous success of failure), controlled modification, combinations thereof, or others. In one example, one or more of the environmental parameters are modified by a bounded random process, using a specified range from the initial environmental parameter, such as creating a modified environmental parameter that is between 75% and 125% of the initial environmental parameter. The number of environmental parameters which are modified can vary based on the desires of the user. Of note, the presentation module 330 can perform multiple modifications of the one or more environmental parameters, multiple iterations of modifications (e.g., multiple modified environments for multiple modified simulations), or combinations thereof.

The generation module 320 can further include instructions to generate a simulation using the one or more modified environmental parameters. The simulation is a presentation of a virtual environment, including rigid objects and various physical parameters, for the control model of an autonomous device to safely interact without harm to the environment or the autonomous device. The simulation can be generated using a variety of environmental parameters, such as a combination of initial environmental parameters and/or modified environmental parameters. The simulation can be a simulation created using the initial environment, the modified environment or combinations thereof. The simulation can be used to test one or more functions of one or more control model for an autonomous device.

The simulation can include the initial and modified environmental parameters, friction, inertia, geometries, weight, surface roughness, and others factors and components involved in the implementation of and interaction with the simulated environment of the simulation. An environment composed of the initial environmental parameters can be referred to as an initial environment. Further, the autonomous device can include at least one of the one or more control models. The one or more control models, as used herein, are models which define the behavior of the autonomous device, such as in response to an input from a simulated environment. In the case of the vehicle 100, the vehicle 100 can include a control model as part of the autonomous driving module 160.

The presentation module 330 can include instructions to present the simulation to a plurality of control models for an autonomous device, wherein each of the plurality of control models provides an information set. The information set is a collection of metrics regarding the performance of the one or more control models in the simulation. The presentation module 330 can then connect with the one or more control models for an autonomous device to present one or more simulations. When presented a simulation, the one or more control models will receive inputs which provide information about objects which exist in the simulated environment. The one or more control models of the autonomous device can then interact with the simulations using the one or more control models, the interaction providing an information set. The simulations based on the initial environmental parameters and/or the modified environmental parameters can be presented to the autonomous device (e.g., the vehicle 100) in substantially the same manner as described above with regards to the initial simulation. The simulations can further be presented to the one or more control models in series or in parallel with one another. In one embodiment, thousands of simulations (e.g., the initial simulation and the modified simulations) are presented simultaneously to the autonomous device. The interaction of the autonomous device, through the control models, with the simulation provides further indications of the functionality and the limitations of the one or more control models. The results of the interaction can then be applied to produce the information sets for each simulation. Using the simulation inputs, the one or more control models can then provide instructions or outputs to the simulation, which inform the simulation of the actions that the autonomous device will perform. Performance of the simulated autonomous device in the simulation can be used to determine which of the one or more control models will perform as desired in an actual or real world environment.

The autonomous device can be as described above, with reference to FIG. 1. In this embodiment, the presentation module 330 can be stored as part of memory 214 in the computing device 200. In the case of the vehicle 100, the one or more control models for the vehicle 100 can interact with the generation module 320 either locally or remotely, such as connecting through a network 380 to the computing device 200. Following the same vehicle example, the one or more control models of the vehicle 100 can then virtually explore the simulation through inputs of the control models as expressed by a virtual autonomous device. Each of the one or more control models will attempt to perform the intended function in the environment, with various levels of success and failure. As the virtual autonomous device explores the simulation and performs a function, the objects of the environment will act as obstacles or interaction points for the virtual autonomous device and provide data regarding the control model performance in that iteration of the simulated environment.

Though the information set is described as being collected at the presentation module 330, this is not necessary. In further embodiments, the presentation module 330 provides the simulation to the selection module 340, described below. In this embodiment, tall of the simulations can be presented to the one or more control models of the autonomous device by the selection module 340. The simulations, including initial simulations and modified simulations, can be presented to each of the one or more control models in series or in parallel. Further, in series or in parallel can be with consideration of the control models, the simulations or both. In one embodiment, the initial simulations and the modified simulations can be presented simultaneously (e.g., in parallel) to the each of the control models simultaneously (e.g., in parallel). In another embodiment, the simulations can be presented sequentially (e.g., in in series) to the each of the control models simultaneously (e.g., in parallel). One skilled in the art will understand the breadth of the combinations, without further explicit recitation.

The selection module 340 can further include instructions to determine a performance metric for each of at least two of the plurality of control models using the corresponding information set. The performance metric is a comparison of the one or more information sets indicating the level of performance on a specific iteration of the simulation or with regards to a specific performance parameter. Each of the control models can be allotted a performance metric. The desirability of a control model can be determined by a predetermined metric, such as overall likelihood of success, success under specific conditions, ability to perform when presented with specific obstacles or challenges, or others as desired. At least one of the one or more control models can then be selected for use in the autonomous device, such as the vehicle 100. Further, the performance metric can be related to overall performance or performance related to a specific portion of the simulations. The performance metric can include success or failure on a number of environmental aspects, such as maneuvering, control, posture, speed, responsiveness, stalling, and other. Level of performance can be based on specific success and failures in the simulations, numbers of successes and failures, comparative level of successes and failures or other rationales.

The selection module 340 can further include instructions to select one of the plurality of control models based on the performance metric. Once the performance parameters are set and the performance metric is determined, the selection module 340 can then select at least one adopted control model from the one or more control models. The adopted control model is the model which performed to the standard set by the user or the system. In one embodiment, the adopted control model is the control model which can be successfully implemented in the vehicle 100 or other autOonomous device for autonomous control. Other embodiments can include a control model for a robotic arm in an assembly plane, for locomotion in an ambulatory robot, or others as desired by the user. In further embodiments, the selection module 340 can include instructions to determine an impact of the environmental parameters on the control models. For example, a specific modification to the environment (e.g., modifying the size of a cup) may lead to a specific type of failure (e.g., inability of the control model to pick up the cup) with other elements of the control model remaining unaffected. The selection module 340 can include the specific impact of the modifications on each individual portion of the control model.

The selection module 340 can further include instructions to track the interaction of a plurality of control models through the virtual autonomous device with the objects of the simulated environment. In this embodiment, more than one control model may be used to control a single autonomous device. By tracking interaction with a plurality of control models with the environment, the generation module 320 can determine which portions of each of the control models of the autonomous driving module 160 function appropriately and which portions of the control system do not function as intended. The information sets for the interactions of the virtual autonomous device, as presented through the control models, can then be stored in the database 310 as part of the simulation data 370. The simulation data 370 is the collected information regarding the physics information, environmental parameters for use in the simulations, and the simulations as presented to the one or more control models. The simulation can be provided by the presentation module 330 one or more times to confirm reproducibility of results, to analyze various control parameters or other features as desired.

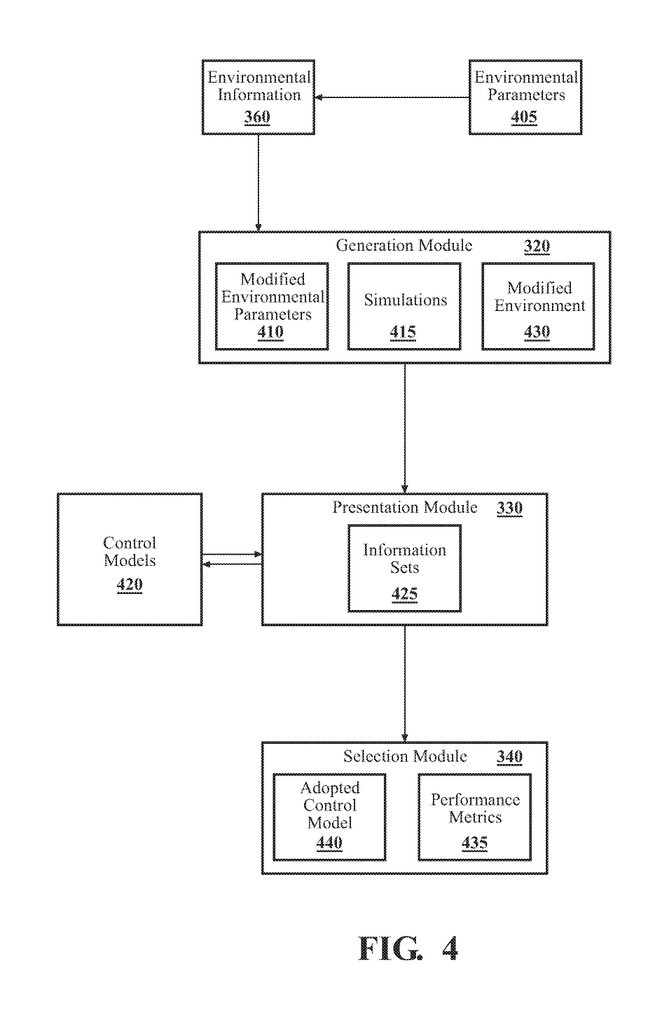

FIG. 4 is a schematic of the probabilistic simulation system 270, according to one or more embodiments. In this embodiment, the simulation includes the implementation of an initial simulation followed sequentially by one or more modified simulation. However, the simulations can be presented in any order, with or without an initial simulation as described, and in series or in parallel, as disclosed in FIG. 3. The probabilistic simulation system 270 receives information about the environmental from one or more available sources, creates a plurality of simulations using perturbations in the environmental parameters, and presents said simulations to the control models of the autonomous device. The probabilistic simulation system 270 then creates information sets from the results of the interaction of the control models and the simulations. The probabilistic simulation system 270 then determines, using the information sets, which control models perform in a desired manner.

The probabilistic simulation system 270 can be initiated through the generation module 320. The generation module 320 can receive the environmental information 360, such as from a sensor system. The environmental information 360 can include the one or more environmental parameters 405. The environmental parameters 405 provide information about one or more objects in the environment. The environmental parameters 405 can be substantially similar to the one or more environmental parameters described with reference to FIG. 3 above. The environmental parameters 405 can be collected from an actual environment or determined from said environment. Further, the environmental parameters 405 can be collected locally or remotely.

The generation module 320 then provides instructions to the processor 204 to modify one or more of the environmental parameters 405. The environmental parameters 405 can be modified to create one or more modified environmental parameters 410. The modified environmental parameters 410 can each have independent modifications for the one or more simulations. The environmental parameters 405 can be modified based on a variety of modification schemes, described above with reference to FIG. 3. The modified environmental parameters 410 can be used to produce one or more modified environments 430. The modified environments 430 can then be incorporated as part of one or more simulations 415. The generation module 320 can then forward the one or more simulations 415, including the modified environments 430, to the presentation module 330.

The presentation module 330 can then present the simulation 415 to the one or more control models 420. The one or more simulations 415, as described above, can be presented to the one or more control models 420 in parallel or in series. The control models 420 can then simulate interaction with the one or more simulations 415 based on the autonomous device being modeled. For example, one or more control models 420 of a vehicle 100 may drive through the modified environment 430 of the one or more simulations 415. In another example, one or more control models 420 of a robotic arm can manipulate an object, as defined by the modified environmental parameters 410, in the modified environment 430 of the one or more simulations 415. The interaction of the one or more control models 420 with the simulation 415 can provide information for the one or more information sets 425. The one or more information sets 425 can include information on the performance and behavior of the autonomous device, as presented through the control model, in the one or more simulations 415. The one or more information sets 425 can be stored as part of the simulation data 370. The one or more information sets 425 can be substantially similar to the information sets described with reference to FIG. 3. The one or more information sets 425 can then be stored as part of the database 310, described with reference to FIG. 3. The modified environment 430 and the one or more simulations 415 can then be forwarded to the presentation module 330.

The selection module 340 can then provide instructions to the processor 204 to determine a performance metric 435 for each of at least two of the plurality of control models using the corresponding information set. The one or more information sets 425 can then be compared by the selection module 340 to produce the performance metric 435. The performance metric 435 is a measure of performance of the one or more control models 420 across the one or more simulations 415. The performance metric 435 can be substantially similar to the performance metric described with reference to FIG. 3. Using the performance metric 435 as guidance, the selection module 340 can then select an adopted control model 44 from the control models 420. The adopted control model 440 can be selected from the one or more control models 420 based on a chosen requirement, such as overall ability to perform, performance for any one of the performance metrics 445, or based on individual desires as established by an end user.

Thus, the probabilistic simulation system 270 provides numerous benefits in testing a control model in simulation. By using modifications in the environment for a simulation, a control model can be tested in numerous mildly or greatly perturbed environments. This allows a user to determine points of success and failure more efficiently. As well, using the probabilistic simulation system 270, failures in the real world can be better avoided or mitigated. Through the use of the probabilistic simulation system 270, simulation testing of control models becomes a more viable method for selection and modification of said control models for real world performance of a function.

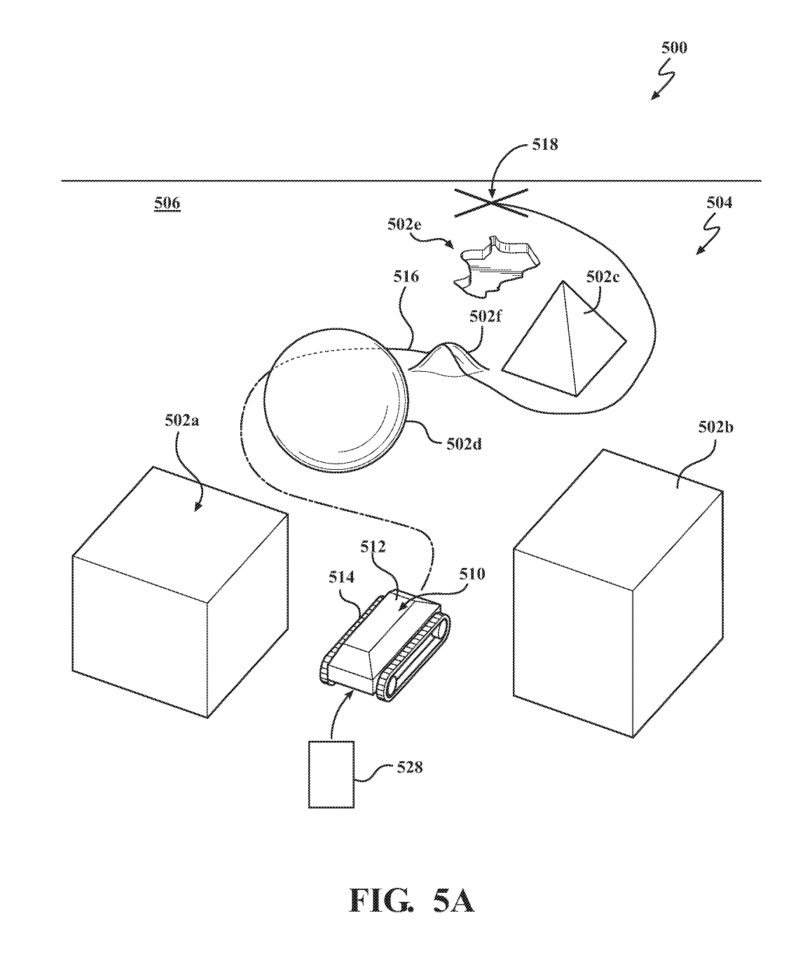

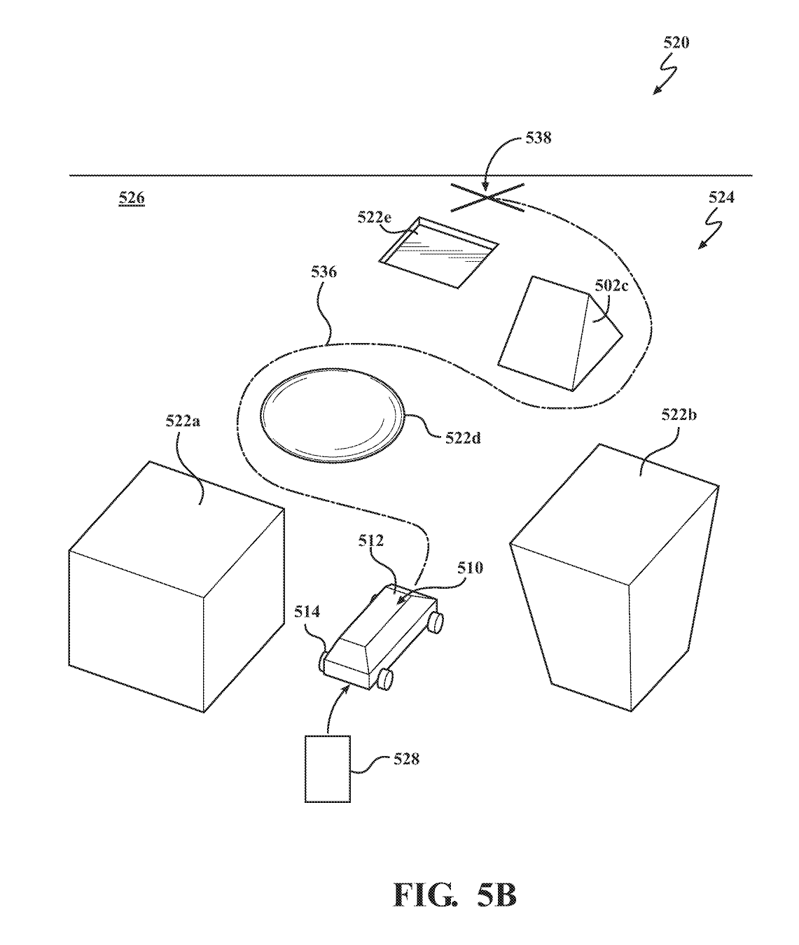

FIGS. 5A and 5B depict simulations incorporating the probabilistic simulation system 270, according to embodiments described herein. In FIG. 5A, we focus on a virtual autonomous device 510, which is controlled by at least one of the control models selected from the one or more control models 450 and depicted by a vehicle. However, it is understood that this is a simplification of an overall simulation, with a variety of possible control models which can be tested in simulation, as described above. In one embodiment, the virtual autonomous device 510 is a simulation of the vehicle 100, including one or more of the components described therein. Components of the vehicle 100, such as the sensor system 120, the vehicle systems 140, or others, can be simulated as part of the simulation, such as the simulation 500 or the simulation 520. FIG. 5A discloses a first simulation 500 having plurality of objects 502a, 502b, 502c, 502d, 502e, and 502f. The first simulation 500 can reflect the environmental parameters in a first state. The first state can be the initial state of the environmental parameters, as detected or received by the generation module 320. The plurality of first objects 502a-502f are part of the first environment 504 in the first simulation 500. In this first simulation 500, the first environment 504 is set up like an obstacle course, with the first objects 502a-502f acting as obstacles for the virtual autonomous device 510 to interact with and overcome.

Here, the generation module 320 creates the first environment 504 and the first simulation 500, using the one or more environmental parameters 405 and/or the one or more modified environmental parameters 410, described above. The environmental parameters 405 and/or the one or more modified environmental parameters 410 shown here can include the dimensions, pose, comparative proximity, surface texture, and other features of the plurality of first objects 502a-502f. The first simulation 500 can further include type of physics that the virtual autonomous device 510 will interact with (e.g., amount of gravity, wind, atmosphere, friction, and others which define the environment generally). Thus, the first simulation 500 incorporates the above parameters and presents then alongside the first environment 504 to the one or more control models as described above with reference to FIGS. 3 and 4. The generation module 320 prepares the one or more simulations as described above and forwards said simulations to the presentation module 330. As shown here, the generation module 320 presents the plurality of first objects 502a-502f as part of the first environment 504. The plurality of first objects 502a-502f are presented in a variety of shapes based on the environmental parameters 405 and/or the modified environmental parameters 410, with the first object 502a and 502b being a cube, the first object 502c being a triangular pyramid, the first object 502d being a sphere, the first object 502e being an amorphous hole, and the first object 502f being a hump or raised surface area. The plurality of first objects 502a-502f are placed in various positions and orientations on a flat surface 506, according to the environmental parameters 405 previously established.

The presentation module 330 can then provide the first simulation 500 to the one or more control models for an autonomous device, the one or more control models 508 interacting with the first simulation using the virtual autonomous device 510. The virtual autonomous device 510 is shown as including a body 512 and treads 514. The one or more control models 508 can provide inputs to the first simulation 500 to control the virtual autonomous device 510 in the first environment 504. The control models 508 can use the body 512 and the treads 514 of the virtual autonomous device 510 for the various interactions with the first simulation 500. Shown here, the control models 508 navigate the first simulation 500 following a first route 516 to an end point 518. The virtual autonomous device 510 begins the first route 516 by passing between first objects 502a and 502b. The virtual autonomous device 510 then continues the first route 516 by moving around the outer edge of first object 502d, between first objects 502 and 502c, over the first object 502f, and around the outer edge of first objects 502 and 502e to reach the end point 518. Each of the first objects 502a-502f increases the level of challenge or difficulty for the virtual autonomous device 510.

As the virtual autonomous device 510 proceeds through the first route 516, the probabilistic simulation system 270 collects information about the details of the virtual autonomous device 510 as part of the one or more information sets 425, using the presentation module 330. In one example, an exemplary control model of the one or more control models 508, using the virtual autonomous device 510, collides with or cannot overcome the object 502e. Data regarding the object, the point of collision, the inputs received and the outputs provided by the exemplary control model are then included in the respective information set of the one or more information sets 425. The remaining control models, or any portion thereof, of the one or more control models 508 can be compared similarly in the first simulation 500. The one or more information sets 425 can then be forwarded to selection modules 340 for determination of the one or more performance metric 435.

FIG. 5B discloses a second simulation 520 having plurality of second objects 522a, 522b, 522c, 522d, and 522e. The presentation module 330 receives the environmental parameters 405 and/or the one or more modified environmental parameters 410. Though depicted here as a single set of environmental parameters 405 and/or the one or more modified environmental parameters 410, as incorporated into the second environment 524, it is understood that a plurality of modified parameters can be used to create a plurality of second environments 524. The plurality of second objects 522a-522e are part of the second environment 524 in the second simulation 520. In the second simulation 520 shown here, the second environment 524 is set up like an obstacle course, with the second objects 522a-522e acting as obstacles for the one or more control models 528 of the virtual autonomous device 530 to interact with and overcome.

Here, the generation module 320 creates the second environment 524 and the second simulation 520, using the environmental parameters 405 and/or the one or more modified environmental parameters 410, described above. The environmental parameters 405 and/or the one or more modified environmental parameters 410 shown here can include the dimensions, pose, comparative proximity, surface texture, and other features of the plurality of second objects 522a-522e, modified as described above. The environmental parameters 405 and/or the one or more modified environmental parameters 410 used in the second simulation 520 can differ from the environmental parameters 405 and/or the one or more modified environmental parameters 410 used in the first simulation 500. The second simulation 520 can further include type of physics that the virtual autonomous device 510 will interact with, as described above. Thus, the second simulation 520 incorporates the above parameters and presents said parameters alongside the second environment 524 to the presentation module 330.

The presentation module 330 then presents the plurality of second objects 522a-522e as part of the second environment 524, to the control models 528 of the virtual autonomous device 530. The plurality of second objects 522a-522e can be modified versions of the plurality of first objects 502a-502e, where the plurality of first objects 502a-502e are modified using one or more modified environmental parameters 410. The virtual autonomous device 530, as controlled by the control models 528, includes wheels 534 attached to a body 532, as these are modified portions of the second environment 524. The plurality of second objects 522a-522e are presented in a variety of shapes based on the related environmental parameters 405, with the second objects 522a being a cube, the second object 522b being a prism, the second object 522c being a triangular prism, the second object 522d being an elongated sphere, and the second object 522e being a square hole. The plurality of second objects 522a-522e are placed in various positions and orientations on a flat surface 526, according to the environmental parameters 405 previously established.

The control model 528, through the virtual autonomous device 530, then follows the second route 536 to the end point 538. Of note, though the second route 536 differs to some degree from the first route 516, in this embodiment, this is not necessary. Further, the modifications for the various environmental parameters (e.g., the change from the treads 514 to the wheels 534) shown here are more extreme to assist in explanation. However, modifications can be very broad or very narrow/subtle in practice. The control model 530 begins the second route 536 by passing between second objects 522a and 522b. The control model 530 then continues the second route 536 by moving around the outer edge of second object 522d, between second objects 522d and 522c, and around the outer edge of second objects 522c and 522e to reach the end point 538.

Each of the second objects 522a-522f alters the level of challenge or difficulty for the one or more control models 528. Using the example from FIG. 5A, the exemplary control model of the one or more control models 528 follows the second route 536 and does not have difficulty overcoming the second object 522e, which is a second version of the first object 502e. As the remaining models of the one or more control models 528 for the virtual autonomous device 530 proceed through the second route 536, the probabilistic simulation system 270 collects information about the details of the interaction of the one or more control models 528 with the second simulation 520 as part of the one or more information sets 425.

The one or more information sets 425 can then be analyzed by the selection module 340 to determine a performance metric 435. As there can be numerous information sets 425 produced for the one or more control models 420, the selection module 340 can produce probabilities for success with each model for numerous conditions, which become part of the performance metrics 435. This allows the probabilistic simulation system 270 to determine which of the control models 420 perform best and select an adopted control model. In this example, the exemplary control model was not able to overcome the object 502e. However, the exemplary control model was able to overcome the second object 522e, a version of the first object 502e with a modified environmental parameter 410. Further in this example, the user can have established that the selected object (e.g., the first object 502e and the second object 522e) must be overcome in 50% of trials as a performance parameter. As such, the performance metric 435 for this performance parameter can show that the exemplary control module overcame the selected object 50% of the time.

In one embodiment, the elements of the plurality of first objects 502a-502f can differ from the elements of the plurality of second objects 522a-522e by an expected measurement error. The elements, as used herein, can include information on dimensions, pose, comparative proximity, surface texture, and other features. The elements can differ by the expected measurement error of the sensor systems employed to provide said information to the physically situated autonomous device that the virtual autonomous device 510 represents. In one example, a laser-based time-of-flight distance measurement device mounted on an autonomous device is used to detect the geometry of a nearby object such as the sphere 502d. Here, the pose and surface geometry of the second object, the elongated sphere 522d, can differ from the sphere 502d, such as by, at most, the maximum measurement error of the sensor. In this manner, the plurality of simulations represents possible real-world scenes, from which the features of the plurality of objects in the plurality of simulations were measured.

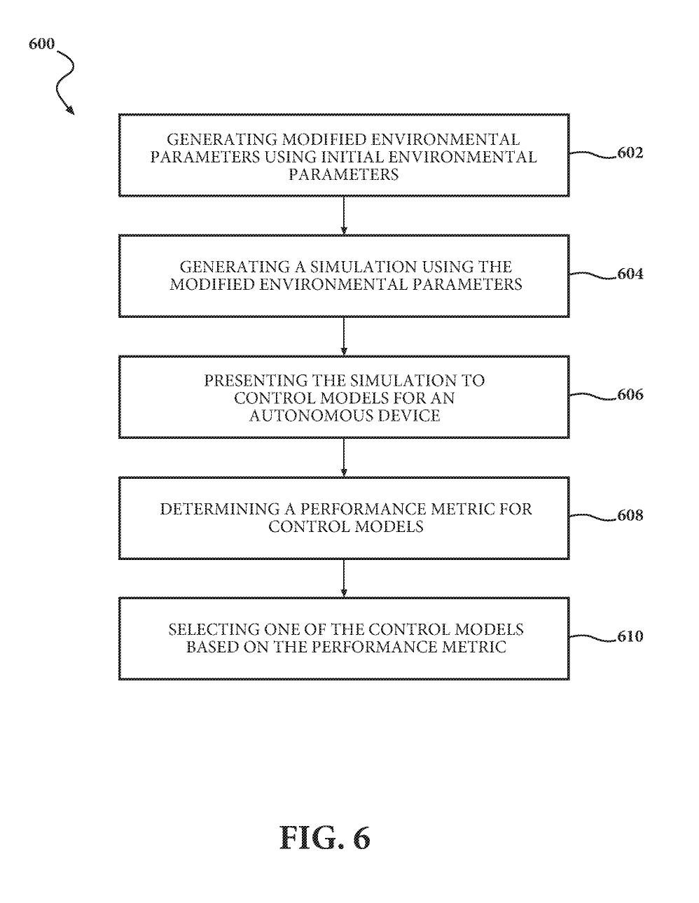

FIG. 6 is a flow diagram of a method 600 for validation of autonomous device control, according to one or more embodiments. The method 600 incudes producing a simulation based on an initial set of environmental parameters and producing modified simulations based on modifications to at least one of the one or more environmental parameters. In this way, the method 600 can test one or more control models against a variety of simulations and environments, thus addressing the imprecision of other types of environmental modeling. The method 600 can begin with generating one or more modified environmental parameters using one or more initial environmental parameters, at 602. A simulation can then be generated using the one or more modified environmental parameters, at 604. The simulation can then be presented to a plurality of control models for an autonomous device, wherein each of the plurality of control models provides an information set, at 606. A performance metric can then be determined for each of at least two of the plurality of control models using the corresponding information set, at 608. One of the plurality of control models can then be selected based on the performance metric, at 610.

The method 600 can begin with generating one or more modified environmental parameters using one or more initial environmental parameters, at 602. In one or more embodiments, the initial environment can include one or more initial environmental parameters. The initial environmental parameters can then be modified, as described with reference to FIG. 3. As described above, the environmental parameters (e.g., the initial environmental parameters and the modified environmental parameters) can be used to determine the shape, size, boundaries, and other features of the various objects and elements in an environment. The method 600 can modify the one or more environmental parameters according to a variety of approaches, including random modification, bounded random modification (modification with a specified range), selected random modification (modification in response to previous success of failure), controlled modification, or others. In one example, one or more of the environmental parameters are modified by a bounded random process, using a specified range from the initial environmental parameter, such as creating a modified environmental parameter that is between 75% and 125% of the initial environmental parameter. Further, the method 600 can perform multiple modifications of the one or more environmental parameters, multiple iterations of modifications (e.g., multiple modified environments for multiple modified simulations), or both.

In one or more embodiments, the generation of the modified environmental parameters can be included as part of a system, such as the probabilistic simulation system 270 described with reference to FIG. 3. The probabilistic simulation system 270 can include the generation module 320. The generation module 320 can include instructions to generate one or more modified environmental parameters using the initial environmental parameters. The one or more initial environmental parameters and the one or more modified environmental parameters, can be stored as part of the environmental information 360 in the database 310. In one or more embodiments, the probabilistic simulation system 270 modifies the one or more environmental parameters of the environment to introduce uncertainty into environmental elements of simulation. Environmental elements can include physical parameters of objects in the environment and physical parameters of the autonomous device. Embodiments herein can employ a Monte Carlo scheme to introduce uncertainty, as described above with reference to FIGS. 3 and 4.

A simulation can then be generated using the one or more modified environmental parameters, at 604. The method 600 can generate an environment using the one or more initial environmental parameters and the one or more modified environmental parameters. The simulation can be then generated using the environment. The simulation can then be presented by the method 600 to the one or more control models of an autonomous device to test one or more functions. The simulation can include the environment, friction, inertia, lengths of links, geometries, weight, surface roughness, and others factors and components involved in the implementation of the virtual world of the simulation. In one or more embodiments, the generation of the simulation can be included as part of a system, such as the probabilistic simulation system 270 described with reference to FIG. 3. The probabilistic simulation system 270 can include the generation module 320. The generation module 320 can include instructions to generate one or more simulations using the initial environmental parameters and/or the modified environmental parameters, as stored in the environmental information 360 in the database 310. The simulation can be stored as part of the simulation data 370. The simulation data 370 can be stored in a database, such as a database 310.

The simulation can then be presented to a plurality of control models for an autonomous device, wherein each of the plurality of control models provides an information set, at 606. The method 600 can include one or more control models for controlling an autonomous device. The control models, as used herein, are models which define the behavior of the autonomous device, such as in a given environment. The control models can present instructions to the simulation which can be used to control the autonomous device. The method 600 can then allow the control models to perform in the initial simulation, creating an information set about said control model. The information set can be substantially similar to the information set described with reference to FIG. 3. The method 600 can further include instructions to track the interaction of the autonomous device, through the control model, with the objects of the environment. This interaction can allow the method 600 to determine which of each of the control models, or portions thereof, function appropriately and which control models do not function as intended. The initial simulation can be provided by the method 600 one or more times to confirm reproducibility of results, to analyze various control parameters or other features as desired.

In one or more embodiments, the presentation of the simulation can be included as part of a system, such as the probabilistic simulation system 270 described with reference to FIG. 3. The probabilistic simulation system 270 can include the presentation module 330. The presentation module 330 can include instructions to present the simulation using the environment, such as a modified environment, to one or more control models for an autonomous device. The control models can be substantially similar to the control models described with reference to FIGS. 3 and 4. The information set can be stored as part of the simulation data 370. The simulation data 370 can be stored in a database, such as a database 310.

A performance metric can then be determined for each of at least two of the plurality of control models using the corresponding information set, at 608. The performance metric is a comparison of the initial information set and modified information sets indicating the level of performance on a specific iteration of the simulation or with regards to a specific parameter's modification. The desirability of a control model can be determined by a performance metric, which is comparison of the one or more environmental parameters to measure of performance in light of a performance parameter. Performance parameters can include overall likelihood of success, success under specific conditions, ability to perform when presented with specific obstacles or challenges, or others as desired. Each of the control models can be allotted a performance metric, based on a comparison between the information sets. Further, the performance metric can be related to overall performance or performance related to a specific portion of the simulations. The performance metric can include success or failure on a number of environmental aspects, such as maneuvering, control, posture, speed, responsiveness, stalling, and other. Level of performance can be based on specific success and failures in the simulations, numbers of successes and failures, comparative level of successes and failures or other rationales. In one or more embodiments, the determination of the performance metric can be included as part of a system, such as the probabilistic simulation system 270 described with reference to FIG. 3. The probabilistic simulation system 270 can include the selection module 340. The selection module 340 can further include instructions to compare the initial information set and the modified information set to determine a performance metric, as described above with reference to FIG. 3.

One of the plurality of control models can then be selected based on the performance metric, at 610. Once the performance parameters are set and the performance metric is determined, the method 600 can then select at least one adopted control model from the one or more control models. The adopted control model is the model which is selected based on performance at the standard set by the user or the system. The standard, which is set by the user, can include high overall performance, performance based on a specific metric, average of success (without regard to maximum performance), or others. In one or more embodiments, the selection of the adopted control model can be included as part of a system, such as the probabilistic simulation system 270 described with reference to FIG. 3. The probabilistic simulation system 270 can include the selection module 340. The selection module 340 can further include instructions to select an adopted control model of the one or more control models using the performance metric, as described above with reference to FIG. 3. The selection module 340 can include a performance standard which provides an indicator to the system 270 of which control model should be selected as the adopted control model. The adopted control model can then be incorporated into an autonomous device, such as the vehicle 100, described with reference to FIG. 1.

Thus the method 600 described herein provides a number of advantages over the previous control model selection schemes. By modifying or perturbing the environment at one or more parameters, the simulations can determine parameters which are critical for the various control models. Further, said modifications can quickly indicate which of a variety of control models perform as desired based on a specific standard. Thus, control models can be tested more effectively prior to implementation, which reduces the possibility that said control model will create a hazard or fail during real world performance.

FIG. 1 will now be discussed in full detail as an example vehicle environment within which the system and methods disclosed herein may operate. In some instances, the vehicle 100 is configured to switch selectively between an autonomous mode, one or more semi-autonomous operational modes, and/or a manual mode. Such switching also referred to as handover when transitioning to a manual mode can be implemented in a suitable manner, now known or later developed. “Manual mode” means that all of or a majority of the navigation and/or maneuvering of the vehicle is performed according to inputs received from a user (e.g., human driver/operator).

In one or more embodiments, the vehicle 100 is an autonomous vehicle. As used herein, “autonomous vehicle” refers to a vehicle that operates in an autonomous mode. “Autonomous mode” refers to navigating and/or maneuvering the vehicle 100 along a travel route using one or more computing devices to control the vehicle 100 with minimal or no input from a human driver/operator. In one or more embodiments, the vehicle 100 is highly automated or completely automated. In one embodiment, the vehicle 100 is configured with one or more semi-autonomous operational modes in which one or more computing devices perform a portion of the navigation and/or maneuvering of the vehicle along a travel route, and a vehicle operator (i.e., driver) provides inputs to the vehicle to perform a portion of the navigation and/or maneuvering of the vehicle 100 along a travel route. Thus, in one or more embodiments, the vehicle 100 operates autonomously according to a particular defined level of autonomy. For example, the vehicle 100 can operate according to the Society of Automotive Engineers (SAE) automated vehicle classifications 0-5. In one embodiment, the vehicle 100 operates according to SAE level 2, which provides for the autonomous driving module 160 controlling the vehicle 100 by braking, accelerating, and steering without operator input but the driver/operator is to monitor the driving and be vigilant and ready to intervene with controlling the vehicle 100 if the autonomous driving module 160 fails to properly respond or is otherwise unable to adequately control the vehicle 100.

The vehicle 100 can include one or more processors 110. In one or more arrangements, the processor(s) 110 can be a main processor of the vehicle 100. For instance, the processor(s) 110 can be an electronic control unit (ECU). The vehicle 100 can include one or more data stores 115 for storing one or more types of data. The data store 115 can include volatile and/or non-volatile memory. Examples of suitable data stores 115 include RAM (Random Access Memory), flash memory, ROM (Read Only Memory), PROM (Programmable Read-Only Memory), EPROM (Erasable Programmable Read-Only Memory), EEPROM (Electrically Erasable Programmable Read-Only Memory), registers, magnetic disks, optical disks, hard drives, or any other suitable storage medium, or any combination thereof. The data store 115 can be a component of the processor(s) 110, or the data store 115 can be operably connected to the processor(s) 110 for use thereby. The term “operably connected,” as used throughout this description, can include direct or indirect connections, including connections without direct physical contact.

In one or more arrangements, the one or more data stores 115 can include map data 116. The map data 116 can include maps of one or more geographic areas. In some instances, the map data 116 can include information or data on roads, traffic control devices, road markings, structures, features, and/or landmarks in the one or more geographic areas. The map data 116 can be in any suitable form. In some instances, the map data 116 can include aerial views of an area. In some instances, the map data 116 can include ground views of an area, including 360-degree ground views. The map data 116 can include measurements, dimensions, distances, and/or information for one or more items included in the map data 116 and/or relative to other items included in the map data 116. The map data 116 can include a digital map with information about road geometry. The map data 116 can be high quality and/or highly detailed.

In one or more arrangement, the map data 116 can include one or more terrain maps 117. The terrain map(s) 117 can include information about the ground, terrain, roads, surfaces, and/or other features of one or more geographic areas. The terrain map(s) 117 can include elevation data in the one or more geographic areas. The map data 116 can be high quality and/or highly detailed. The terrain map(s) 117 can define one or more ground surfaces, which can include paved roads, unpaved roads, land, and other things that define a ground surface.

In one or more arrangement, the map data 116 can include one or more static obstacle maps 118. The static obstacle map(s) 118 can include information about one or more static obstacles located within one or more geographic areas. A “static obstacle” is a physical object whose position does not change or substantially change over a period of time and/or whose size does not change or substantially change over a period of time. Examples of static obstacles include trees, buildings, curbs, fences, railings, medians, utility poles, statues, monuments, signs, benches, furniture, mailboxes, large rocks, hills. The static obstacles can be objects that extend above ground level. The one or more static obstacles included in the static obstacle map(s) 118 can have location data, size data, dimension data, material data, and/or other data associated with it. The static obstacle map(s) 118 can include measurements, dimensions, distances, and/or information for one or more static obstacles. The static obstacle map(s) 118 can be high quality and/or highly detailed. The static obstacle map(s) 118 can be updated to reflect changes within a mapped area.

The one or more data stores 115 can include sensor data 119. In this context, “sensor data” means any information about the sensors that the vehicle 100 is equipped with, including the capabilities and other information about such sensors. As will be explained below, the vehicle 100 can include the sensor system 120. The sensor data 119 can relate to one or more sensors of the sensor system 120. As an example, in one or more arrangements, the sensor data 119 can include information on one or more LIDAR sensors 124 of the sensor system 120.

In some instances, at least a portion of the map data 116 and/or the sensor data 119 can be located in one or more data stores 115 located onboard the vehicle 100. Alternatively, or in addition, at least a portion of the map data 116 and/or the sensor data 119 can be located in one or more data stores 115 that are located remotely from the vehicle 100.

As noted above, the vehicle 100 can include the sensor system 120. The sensor system 120 can include one or more sensors. “Sensor” means any device, component and/or system that can detect, and/or sense something. The one or more sensors can be configured to detect, and/or sense in real-time. As used herein, the term “real-time” means a level of processing responsiveness that a user or system senses as sufficiently immediate for a particular process or determination to be made, or that enables the processor to keep up with some external process.

In arrangements in which the sensor system 120 includes a plurality of sensors, the sensors can function independently from each other. Alternatively, two or more of the sensors can work in combination with each other. In such a case, the two or more sensors can form a sensor network. The sensor system 120 and/or the one or more sensors can be operably connected to the processor(s) 110, the data store(s) 115, and/or another element of the vehicle 100 (including any of the elements shown in FIG. 1). The sensor system 120 can acquire data of at least a portion of the external environment of the vehicle 100 (e.g., nearby vehicles).

The sensor system 120 can include any suitable type of sensor. Various examples of different types of sensors will be described herein. However, it will be understood that the embodiments are not limited to the particular sensors described. The sensor system 120 can include one or more vehicle sensors 121. The vehicle sensor(s) 121 can detect, determine, and/or sense information about the vehicle 100 itself. In one or more arrangements, the vehicle sensor(s) 121 can be configured to detect, and/or sense position and orientation changes of the vehicle 100, such as, for example, based on inertial acceleration. In one or more arrangements, the vehicle sensor(s) 121 can include one or more accelerometers, one or more gyroscopes, an inertial measurement unit (IMU), a dead-reckoning system, a global navigation satellite system (GNSS), a global positioning system (GPS), a navigation system 147, and/or other suitable sensors. The vehicle sensor(s) 121 can be configured to detect, and/or sense one or more characteristics of the vehicle 100. In one or more arrangements, the vehicle sensor(s) 121 can include a speedometer to determine a current speed of the vehicle 100.

Alternatively, or in addition, the sensor system 120 can include one or more environment sensors 122 configured to acquire, and/or sense driving environment data. “Driving environment data” includes and data or information about the external environment in which an autonomous vehicle is located or one or more portions thereof. For example, the one or more environment sensors 122 can be configured to detect, quantify and/or sense obstacles in at least a portion of the external environment of the vehicle 100 and/or information/data about such obstacles. Such obstacles may be stationary objects and/or dynamic objects. The one or more environment sensors 122 can be configured to detect, measure, quantify and/or sense other things in the external environment of the vehicle 100, such as, for example, lane markers, signs, traffic lights, traffic signs, lane lines, crosswalks, curbs proximate the vehicle 100, off-road objects, etc.

Various examples of sensors of the sensor system 120 will be described herein. The example sensors may be part of the one or more environment sensors 122 and/or the one or more vehicle sensors 121. Moreover, the sensor system 120 can include operator sensors that function to track or otherwise monitor aspects related to the driver/operator of the vehicle 100. However, it will be understood that the embodiments are not limited to the particular sensors described.

As an example, in one or more arrangements, the sensor system 120 can include one or more radar sensors 123, one or more LIDAR sensors 124, one or more sonar sensors 125, and/or one or more cameras 126. In one or more arrangements, the one or more cameras 126 can be high dynamic range (HDR) cameras, infrared (IR) cameras and so on. In one embodiment, the cameras 126 include one or more cameras disposed within a passenger compartment of the vehicle for performing eye-tracking on the operator/driver in order to determine a gaze of the operator/driver, an eye track of the operator/driver, and so on.

The vehicle 100 can include an input system 130. An “input system” includes any device, component, system, element or arrangement or groups thereof that enable information/data to be entered into a machine. The input system 130 can receive an input from a vehicle passenger (e.g. a driver or a passenger). The vehicle 100 can include an output system 135. An “output system” includes any device, component, or arrangement or groups thereof that enable information/data to be presented to a vehicle passenger (e.g., a person, a vehicle passenger, etc.).

The vehicle can further include a communication system 131. The communication system 131 can be include a display device 132, audio devices 133 (e.g., speakers and microphones), and one or more input devices 134. The one or more input devices can include sensors, such as cameras, infrared devices, biometric devices, or others. The input devices 134 can further include a touch screen or manual buttons. The communications system can be in communication with the probabilistic simulation system 270, either locally or remotely, such as through a network 190. The communication system 131 can be connected with the vehicle permanently or semi-permanently. Further, the communication system 131 can be divided into components, with portions thereof being permanently part of the vehicle 100, while other components of the communication system 131 can be removed.

The vehicle 100 can include one or more vehicle systems 140. Various examples of the one or more vehicle systems 140 are shown in FIG. 1. However, the vehicle 100 can include more, fewer, or different vehicle systems. It should be appreciated that although particular vehicle systems are separately defined, each or any of the systems or portions thereof may be otherwise combined or segregated via hardware and/or software within the vehicle 100. The vehicle 100 can include a propulsion system 141, a braking system 142, a steering system 143, throttle system 144, a transmission system 145, a signaling system 146, and/or a navigation system 147. Each of these systems can include one or more devices, components, and/or combination thereof, now known or later developed.

The navigation system 147 can include one or more devices, sensors, applications, and/or combinations thereof, now known or later developed, configured to determine the geographic location of the vehicle 100 and/or to determine a travel route for the vehicle 100. The navigation system 147 can include one or more mapping applications to determine a travel route for the vehicle 100. The navigation system 147 can include a global positioning system, a local positioning system or a geolocation system.

The processor(s) 110, and/or the autonomous driving module(s) 160 can be operably connected to communicate with the various vehicle systems 140 and/or individual components thereof. For example, returning to FIG. 1, the processor(s) 110 and/or the autonomous driving module(s) 160 can be in communication to send and/or receive information from the various vehicle systems 140 to control the movement, speed, maneuvering, heading, direction, etc. of the vehicle 100. The processor(s) 110, the probabilistic simulation system 270, and/or the autonomous driving module(s) 160 may control some or all of these vehicle systems 140 and, thus, may be partially or fully autonomous.

The processor(s) 110 and/or the autonomous driving module(s) 160 can be operably connected to communicate with the various vehicle systems 140 and/or individual components thereof. For example, returning to FIG. 1, the processor(s) 110 and/or the autonomous driving module(s) 160 can be in communication to send and/or receive information from the various vehicle systems 140 to control the movement, speed, maneuvering, heading, direction, etc. of the vehicle 100. The processor(s) 110, the probabilistic simulation system 270, and/or the autonomous driving module(s) 160 may control some or all of these vehicle systems 140.

The vehicle 100 can include one or more actuators 150. The actuators 150 can be any element or combination of elements operable to modify, adjust and/or alter one or more of the vehicle systems 140 or components thereof to responsive to receiving signals or other inputs from the processor(s) 110 and/or the autonomous driving module(s) 160. Any suitable actuator can be used. For instance, the one or more actuators 150 can include motors, pneumatic actuators, hydraulic pistons, relays, solenoids, and/or piezoelectric actuators, just to name a few possibilities.

The vehicle 100 can include one or more modules, at least some of which are described herein. The modules can be implemented as computer-readable program code that, when executed by a processor 110, implement one or more of the various processes described herein. The processor 110 can be a device, such as a CPU, which is capable of receiving and executing one or more threads of instructions for the purpose of performing a task. One or more of the modules can be a component of the processor(s) 110, or one or more of the modules can be executed on and/or distributed among other processing systems to which the processor(s) 110 is operably connected. The modules can include instructions (e.g., program logic) executable by one or more processor(s) 110. Alternatively, or in addition, one or more data store 115 may contain such instructions.

In one or more arrangements, one or more of the modules described herein can include artificial or computational intelligence elements, e.g., neural network, fuzzy logic or other machine learning algorithms. Further, in one or more arrangements, one or more of the modules can be distributed among a plurality of the modules described herein. In one or more arrangements, two or more of the modules described herein can be combined into a single module.

The vehicle 100 can include one or more autonomous driving modules 160. The autonomous driving module(s) 160 can be configured to receive data from the sensor system 120 and/or any other type of system capable of capturing information relating to the vehicle 100 and/or the external environment of the vehicle 100. In one or more arrangements, the autonomous driving module(s) 160 can use such data to generate one or more driving scene models. The autonomous driving module(s) 160 can determine position and velocity of the vehicle 100. The autonomous driving module(s) 160 can determine the location of obstacles, or other environmental features including traffic signs, trees, shrubs, neighboring vehicles, pedestrians, etc.

The autonomous driving module(s) 160 can be configured to receive, and/or determine location information for obstacles within the external environment of the vehicle 100 for use by the processor(s) 110, and/or one or more of the modules described herein to estimate position and orientation of the vehicle 100, vehicle position in global coordinates based on signals from a plurality of satellites, or any other data and/or signals that could be used to determine the current state of the vehicle 100 or determine the position of the vehicle 100 with respect to its environment for use in either creating a map or determining the position of the vehicle 100 in respect to map data. The autonomous driving module(s) 160 can be configured to determine travel path(s), current autonomous driving maneuvers for the vehicle 100, future autonomous driving maneuvers and/or modifications to current autonomous driving maneuvers based on data acquired by the sensor system 120, driving scene models, and/or data from any other suitable source.

Detailed embodiments are disclosed herein. However, it is to be understood that the disclosed embodiments are intended only as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-5, but the embodiments are not limited to the illustrated structure or application.

The flowcharts and block diagrams in the figures illustrate the architecture, functionality, and operation of possible embodiments of systems, methods and computer program products according to various embodiments. In this regard, each block in the flowcharts or block diagrams can represent a module, segment, or portion of code, which comprises one or more executable instructions for implementing the specified logical function(s). It should also be noted that, in some alternative embodiments, the functions noted in the block can occur out of the order noted in the Figures. For example, two blocks shown in succession can, in fact, be executed substantially concurrently, or the blocks can sometimes be executed in the reverse order, depending upon the functionality involved.

The systems, components and/or methods described above can be realized in hardware or a combination of hardware and software and can be realized in a centralized fashion in one processing system or in a distributed fashion where different elements are spread across several interconnected processing systems. Any kind of processing system or other apparatus adapted for carrying out the methods described herein is suited. A typical combination of hardware and software can be a processing system with computer-usable program code that, when being loaded and executed, controls the processing system such that it carries out the methods described herein. The systems, components and/or methods also can be embedded in a computer-readable storage, such as a computer program product or other data programs storage device, readable by a machine, tangibly embodying a program of instructions executable by the machine to perform methods and methods described herein. These elements also can be embedded in an application product which comprises all the features enabling the embodiment of the methods described herein and, which when loaded in a processing system, is able to carry out these methods.

Furthermore, arrangements described herein can take the form of a computer program product embodied in one or more computer-readable media having computer-readable program code embodied or embedded, such as stored thereon. Any combination of one or more computer-readable media can be utilized. The computer-readable medium can be a computer-readable signal medium or a computer-readable storage medium. The phrase “computer-readable storage medium” means a non-transitory storage medium. A computer-readable storage medium can be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: an electrical connection having one or more wires, a portable computer diskette, a hard disk drive (HDD), a solid state drive (SSD), a random access memory (RAM), a read-only memory (ROM), an erasable programmable read-only memory (EPROM or Flash memory), an optical fiber, a portable compact disc read-only memory (CD-ROM), a digital versatile disc (DVD), an optical storage device, a magnetic storage device, or any suitable combination of the foregoing. In the context of this document, a computer-readable storage medium can be any tangible medium that can contain, or store a program for use by or in connection with an instruction execution system, apparatus, or device.

Program code embodied on a computer-readable medium can be transmitted using any appropriate medium, including but not limited to wireless, wireline, optical fiber, cable, RF, etc., or any suitable combination of the foregoing. Computer program code for carrying out operations for aspects of the present arrangements can be written in any combination of one or more programming languages, including an object-oriented programming language such as Java™, Smalltalk, C++ or the like and conventional procedural programming languages, such as the “C” programming language or similar programming languages. The program code can execute entirely on the user's computer, partly on the user's computer, as a stand-alone software package, partly on the user's computer and partly on a remote computer, or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B and C” includes A only, B only, C only, or any combination thereof (e.g., AB, AC, BC or ABC).

While the foregoing is directed to embodiments of the disclosed devices, systems, and methods, other and further embodiments of the disclosed devices, systems, and methods can be devised without departing from the basic scope thereof. The scope thereof is determined by the claims that follow.

What is claimed is:

1. A probabilistic simulation system for validation of autonomous device control, comprising:
one or more processors; and
a memory communicably coupled to the one or more processors and storing:
a generation module including instructions that when executed by the one or more processors cause the one or more processors to generate one or more modified environmental parameters using one or more initial environmental parameters, and to generate a simulation using the one or more modified environmental parameters;
a presentation module including instructions that when executed by the one or more processors cause the one or more processors to present the simulation to a plurality of control models for an autonomous device, wherein each of the plurality of control models provides an information set; and
a selection module including instructions that when executed by the one or more processors cause the one or more processors to determine a performance metric for each of at least two of the plurality of control models using the corresponding information set, and to select one of the plurality of control models based on the performance metric.

2. The probabilistic simulation system of claim 1, wherein the information set includes an initial information set and one or more modified information sets.

3. The probabilistic simulation system of claim 1, wherein the modified environmental parameters are generated using one of a random modification, a bounded random modification, a selected random modification, a controlled modification, and combinations thereof.

4. The probabilistic simulation system of claim 3, wherein the modified environmental parameters are generated using a random modification according to a Monte Carlo scheme.

5. The probabilistic simulation system of claim 1, wherein at least one of the modified environmental parameters is a physical characteristic of the autonomous device.

6. The probabilistic simulation system of claim 1, wherein the generation module further includes instructions to collect environmental information, using a sensor system, from one or more real world environments.

7. The probabilistic simulation system of claim 1, wherein the performance metric is a measure of success to failure in performing a task in the simulation.

8. The probabilistic simulation system of claim 1, wherein the selection module further includes instructions to determine an impact of the initial environmental parameters on the one or more control models.

9. A non-transitory computer-readable medium for validation of autonomous device control and storing instructions that when executed by one or more processors cause the one or more processors to:
generate one or more modified environmental parameters using one or more initial environmental parameters;
generate a simulation using the one or more modified environmental parameters;
present the simulation to a plurality of control models for an autonomous device, wherein each of the plurality of control models provides an information set;
determine a performance metric for each of at least two of the plurality of control models using the corresponding information set; and
select one of the plurality of control models based on the performance metric.

10. The non-transitory computer-readable medium of claim 9, wherein the information set includes an initial information set and a modified information set.

11. The non-transitory computer-readable medium of claim 9, wherein the modified environmental parameters are generated using one of a random modification, a bounded random modification, a selected random modification, a controlled modification, and combinations thereof.

12. The non-transitory computer-readable medium of claim 11, wherein the modified environmental parameters are generated using a random modification according to a Monte Carlo scheme.

13. The non-transitory computer-readable medium of claim 9, wherein at least one of the modified environmental parameters is a physical characteristic of the autonomous device.

14. The non-transitory computer-readable medium of claim 9, further including instructions to collect environmental information, using a sensor system, from one or more real world environments.

15. The non-transitory computer-readable medium of claim 9, further including instructions to determine an impact of the initial environmental parameters on the plurality of control models.

16. A method for validation of autonomous device control, comprising:
generating one or more modified environmental parameters using one or more initial environmental parameters;
generating a simulation using the one or more modified environmental parameters;
presenting the simulation to a plurality of control models for an autonomous device, wherein each of the plurality of control models provides an information set;
determining a performance metric for each of at least two of the plurality of control models using the corresponding information set; and
selecting one of the plurality of control models based on the performance metric.

17. The method of claim 16, wherein the initial information set includes environmental information as related to performance information for the one or more control models.

18. The method of claim 16, wherein the modified environmental parameters are generated using one of a random modification, a bounded random modification, a selected random modification, a controlled modification, and combinations thereof.

19. The method of claim 16, wherein at least one of the modified environmental parameters is a physical characteristic of the autonomous device.

20. The method of claim 16, further including instructions to determine an impact of the initial environmental parameters on the plurality of control models.
